(19) United States
(12) Patent Application Publication
(10) Pub. No.: US 2020/0126829 A1
(43) Pub. Date: Apr. 23, 2020

(54) MAINTENANCE CONTROL METHOD OF CONTROLLING MAINTENANCE OF PROCESSING DEVICE AND CONTROL DEVICE

(71) Applicant: Tokyo Electron Limited, Tokyo (JP)

(72) Inventors: Hidefumi MATSUI, Yamanashi (JP); Yudo SUGAWARA, Iwate (JP); Hiroshi NAGAIKE, Miyagi (JP); Yasutoshi UMEHARA, Tokyo (JP)

(21) Appl. No.: 16/094,060

(22) PCT Filed: Apr. 10, 2017
(86) PCT No.: PCT/JP2017/014669

§ 371 Date: Oct. 16, 2018

(30) Foreign Application Priority Data
Apr. 19, 2016 (JP) 2016-083960

(51) Int. Cl. H01L 21/67; G01N 29/14; G05B 19/042

(52) U.S. Cl. CPC H01L 21/67276; G05B 2219/24001; G05B 19/042; G01N 29/14

(57) ABSTRACT

There is provided a maintenance control method of controlling a processing device including determining whether a temperature of a component part of the processing device that processes a substrate changes at least 5° C. or a preset temperature is changed by at least 5° C., determining whether at least a predetermined number of a first vibration is included in vibration data detected by a vibration sensor provided in the processing device in response to a timing when the temperature of the component part of the processing device that processes the substrate is determined to change at least 5° C. or the preset temperature is determined to be changed by at least 5° C., the first vibration having a frequency of at most 100 kHz and having at least a predetermined vibration intensity continued for at least 300 μs, determining, in a case where the at least predetermined number of the first vibration is determined to be included in the vibration data, whether at least a predetermined number of a second vibration is included in the vibration data detected by the vibration sensor provided in the processing device, the second vibration having a frequency mainly in a range of 100 kHz to 300 kHz and having at least a predetermined vibration intensity to be ended within at most 300 μs, and analyzing, in a case where the at least predetermined number of the second vibration is determined to be included in the vibration data, a state of the processing device based on the vibration data including the first vibration and the second vibration.

### TECHNICAL FIELD

The present invention relates to a maintenance control method of controlling maintenance of a processing device and a control device.

### BACKGROUND ART

There is proposed a technique of detecting abnormal electrical discharge of an etching device using a vibration sensor such as an Acoustic Emission (AE) sensor and an acceleration sensor (see, for example, NON-PATENT DOCUMENT 1). Further, proposed is a technique of detecting abnormity of a driving unit in a processing device using a vibration sensor (see, for example, PATENT DOCUMENT 1 to PATENT DOCUMENT 4).

### BACKGROUND DOCUMENT

NON-PATENT DOCUMENT 1: J. Phys. D: Appl. Phys. 41(2008)035209(9pp)“Dynamical properties of acoustic emission by anomalous discharge in plasma processing system”

PATENT DOCUMENT 1: Japanese Laid-Open Patent Application No. 2015-218652

PATENT DOCUMENT 2: Japanese Laid-Open Patent Application No. 2002-202184

PATENT DOCUMENT 3: Japanese Laid-Open Patent Application No. Hei. 11-51913

PATENT DOCUMENT 4: Japanese Laid-Open Patent Application No. Hei. 6-217421

### DISCLOSURE OF THE INVENTION

### Problems to be Solved by the Invention

However, in the above NON-PATENT DOCUMENT and PATENT DOCUMENTS, abnormity in a processing device and a driving unit is discovered using vibration data detected by a vibration sensor. Therefore, in the above NON-PATENT DOCUMENT and PATENT DOCUMENTS, it is difficult to previously prevent the abnormity from being generated by discovering and handling a state change inside the processing device.

In the processing device such as an etching device, a reaction product is generated during the process and is attached onto an inner wall during a process. Therefore, after a reaction product is deposited to a certain extent, cleaning is performed to maintain the processing device.

A cleaning cycle is a predetermined time duration uniquely set from past experience. Specifically, in a case where a factor of determining a cleaning cycle of the processing device is generation of a particle, the particle is periodically checked to determine a time duration before a drop of yield ratio of a product wafer manufactured by a processing device and this time duration is determined as the predetermined time duration. Therefore, there may be a case where a particle is produced when cleaning has not been conducted before the predetermined time duration passes, or a case where cleaning is conducted after the predetermined time duration passes even though the particle is not produced.

Especially, when a time for cleaning delays in a case where maintenance by cleaning is necessary at a time earlier than a predetermined cycle, the yield ratio of the product wafer processed by the processing device drops due to recent diversification of the process. On the other hand, when cleaning is conducted in a case where the inside of the processing device is in a state of enabling the process to be performed, a time usable for the process decreases so as to decrease the yield ratio. Especially, in a case of dry cleaning between two types of cleaning, namely dry cleaning and wet cleaning, resource such as cleaning gas is uselessly wasted.

To solve the above problem, according to an aspect, the object of the present invention is to control a timing of maintaining the processing device.

### Means for Solving Problems

There is provided a maintenance control method of controlling a processing device performed by a computer including determining whether a temperature of a component part of the processing device that processes a substrate changes at least 5° C. or a preset temperature is changed by at least 5° C., determining whether at least a predetermined number of a first vibration is included in vibration data detected by a vibration sensor provided in the processing device in response to a timing when the temperature of the component part of the processing device that processes the substrate is determined to change at least 5° C. or the preset temperature is determined to be changed by at least 5° C., the first vibration having a frequency of at most 100 kHz and having at least a predetermined vibration intensity continued for at least 300 μs, determining, in a case where the at least predetermined number of the first vibration is determined to be included in the vibration data, whether at least a predetermined number of a second vibration is included in the vibration data detected by the vibration sensor provided in the processing device, the second vibration having a frequency mainly in a range of 100 kHz to 300 kHz and having at least a predetermined vibration intensity to be ended within at most 300 μs, and analyzing, in a case where the at least predetermined number of the second vibration is determined to be included in the vibration data, a state of the processing device based on the vibration data including the first vibration and the second vibration.

### Effect of the Invention

According to a first aspect, a timing of maintaining the processing device can be controlled.

### BRIEF DESCRIPTION OF DRAWINGS

FIG. 1 illustrates an example of a plasma process apparatus and a control device according to an embodiment of the present invention.

FIG. 2 illustrates an example of a functional structure of the control device according to the embodiment of the present invention.

FIG. 3 illustrates a frequency bandwidth of vibration detected by a sensor.

FIG. 4 is a flowchart illustrating an example of a maintenance control process of the embodiment of the present invention.

FIG. 5 illustrates an example of vibration data (before converting frequency) according to the embodiment of the present invention.

FIG. 6 illustrates another example of vibration data (after converting frequency) according to the embodiment of the present invention.

### DETAILED DESCRIPTION OF THE PREFERRED EMBODIMENTS

Hereinafter, an embodiment of the present invention is explained with reference to drawings. Through the specification and the figures, the same references symbols are used for portions having substantially the same structure, and repetitive explanations of these portions are omitted.

### Overall Structure of Plasma Processing Apparatus

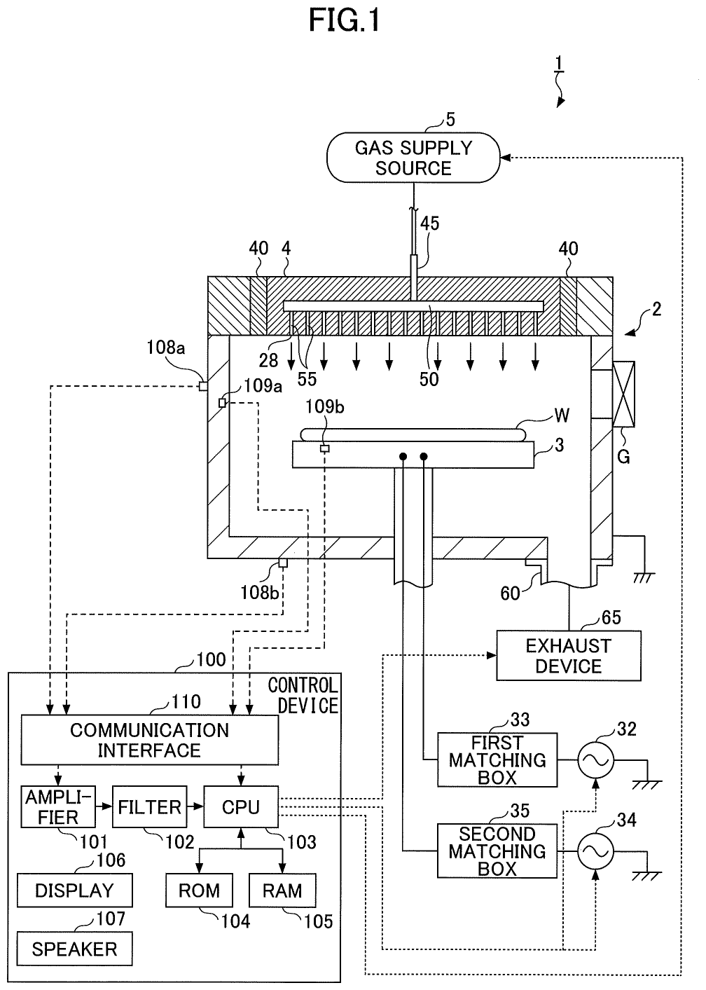

At first, referring to FIG. 1, an example of the overall structure of a plasma processing apparatus 1 of an embodiment of the present invention is described. FIG. 1 illustrates an example of a vertical section of a plasma processing apparatus and an example of hardware structure of a control device. Within the embodiment, a capacitively-coupled plasma etching device is exemplified as the plasma processing apparatus 1. The plasma processing apparatus 1 is an example of a processing device that processes the substrate.

The plasma processing apparatus 1 of this embodiment is not specifically limited and may be an etching process apparatus that etches a semiconductor wafer W (hereinafter, referred to as a “wafer W”) or a film deposition apparatus that performs film deposition on the wafer W by Chemical Vapor Deposition (CVD). The plasma processing apparatus 1 may be a film deposition apparatus performing film deposition on the wafer W by Physical Vapor Deposition (PVD), an Atomic Layer Etching (ALE) apparatus, an Atomic Layer Deposition (ALE) apparatus, or a coater developer.

This plasma processing apparatus 1 includes a processing container 2 made of a conductive material such as aluminum and a gas supply source 5 for supplying a gas into the processing container 2. The processing container 2 is electrically grounded. Inside the processing container 2, a lower electrode 3 and an upper electrode 4 that is arranged to face the lower electrode 3 in parallel with the lower electrode 3. The lower electrode 3 functions as a mounting stage on which the wafer W is mounted. Referring to FIG. 1, a first high-frequency power source 32 is connected with the lower electrode 3 through a first matching box 33, and a second high-frequency power source 34 is connected with the lower electrode 3 through a second matching box 35. The first high-frequency power source 32 applies first high frequency power (high-frequency power HF for generating plasma) having the first frequency y to the lower electrode 3. The second high-frequency power source 34 applies second high frequency power (high-frequency power LF for drawing ions) having a second frequency lower than the first frequency y to the lower electrode 3.

The first matching box 33 matches a load impedance with an internal impedance (an output impedance) of the first high-frequency power source 32. The second matching box 35 matches the load impedance with an internal impedance (an output impedance) of the second high-frequency power source 34. With this, in a case where plasma is generated inside the processing container 2, the internal impedance and the load impedance function so as to seemingly match in each of the first high-frequency power source 32 and the second high-frequency power source 34.

The upper electrode 4 is attached to a ceiling portion of the processing container 2 through a shield ring 40 covering and sealing a peripheral edge portion of the upper electrode 4. A diffusion chamber 50 for diffusing a gas introduced from the gas supply source 5 is provided in the upper electrode 4. A gas introduction port 45 is formed in the diffusion chamber 50. The gas output from the gas supply source 5 is supplied into the diffusion chamber 50 through gas introduction port 45 and is further supplied inside the processing container 2 through the gas flow path 55 from an opening 28. Thus structured upper electrode 4 also functions as a gas shower head for supplying the gas.

An exhaust port 60 is formed on the bottom surface of the processing container 2, and the inside of the processing container 2 is exhausted by an exhaust device 65 connected to the exhaust port 60. With this, the inside of the processing container 2 can be maintained to have a predetermined degree of vacuum.

A gate valve G is provided in the sidewall 11 of the processing container 2. The gate valve G opens and closes the carry-in and carry-out port when the wafer W is carried in or carried out of the processing container 2. Acoustic Emission (AE) sensors 108a and 108b are respectively attached to a side portion and a bottom portion on a side of the outer wall of the processing container 2. Hereinafter, the sensors 108a and 108b are generally called an AE sensor 108.

The AE sensor 108 detects vibration caused by thermal expansion of the component parts (parts) of the processing container 2. Further, the AE sensor 108 detects vibration caused by a crack generated in an attached extraneous matter (a reaction product) inside the processing container 2 and on the surface of the parts. The number of the AE sensors 108 may be one or at least two. However, it cannot be known where a predetermined vibration is generated inside the processing container 2. Therefore, it is preferable to dispose multiple AE sensors 108 on the outer wall such as the outer wall at the side portion of the processing container 2, the bottom portion of the processing container 2, and the ceiling portion in order to enable the vibration generated inside the processing container 2 to be accurately detected.

Further, the AE sensor 108 may be installed inside the processing container 2. In this case, it is preferable that the AE sensor 108 is embedded into the inner wall of the processing container 2 or the inside of the mounting stage (the lower electrode 3) so as to prevent the AE sensor 108 from being exposed in the plasma space and the plasma process from being influenced. However, a sheet-like AE sensor 108 may be bonded to the inner wall of the processing container 2.

A temperature sensor 109a is embedded in the sidewall of the processing container 2, and a temperature sensor 109b is embedded in the lower electrode 3 (a mounting stage). The temperature sensor 109a detects the temperature of the processing container 2. The temperature sensor 109b detects the temperature of the mounting stage or the wafer temperature (hereinafter, referred to as a “temperature of the mounting stage or the like”). The temperature sensors 109a and 109b collectively mean a temperature sensor 109. The temperature sensor 109 may be one or at least two. The temperature sensor 109 may be embedded inside the ceiling portion of the processing container 2.

It is preferable to place the AE sensor 108 at a position close to the temperature sensor 109. By closely arranging the AE sensor 108 and the temperature sensor 109, it becomes easier to make a timing of the change in the AE sensor 108 and the temperature sensor 109 a standard of determining generation of the vibration and a place of a generation source of the vibration may be specified.

### Hardware Structure of the Control Device

A control unit 100 is provided to control an overall operation of the plasma processing apparatus 1. Referring to FIG. 1, an example of the hardware structure of the control device is described. The control device 100 includes an amplifier 101, a filter 102, a CPU (Central Processing Unit) 103, a ROM (Read Only Memory) 104, a RAM (Random Access Memory) 105, a display 106, a speaker 107, and a communication interface 110.

The communication interface 110 receives a signal indicating the vibration detected by the AE sensor 108. The communication interface 110 receives a signal indicating the vibration detected by the temperature sensor 109. The communication interface 110 receives the signals from the sensors by wired communication. The communication interface 110 may receive the signals from the sensors by wireless communication.

The amplifier 101 amplifies the received vibration signal. The filter 102 removes an error signal corresponding to the noise from the amplified vibration signal. An example of the error signal removed by the filter 102 is a signal whose vibration intensity peak does not continue for a predetermined time period or more. The vibration signal whose error signal is removed from the vibration signal by the filter 102 is input into the CPU 103 and is subject to frequency conversion. By removing the error signal from the vibration signal, it is possible to reduce a load of a frequency conversion process of converting the frequency of the vibration signal. The CPU 103 executes the frequency conversion process of the vibration signal, the analyzation process of data after frequency conversion, a maintenance determination process based on the result of the analyzation, a temperature change determination process based on the temperature detected by the temperature sensor 109, and so on.

A basic program or the like executed by the control device 100 is stored in the ROM 104. A recipe is stored in the RAM 105. Control information of the plasma processing apparatus 1 with respect to the process conditions (etching conditions or the like) is set to the recipe. The control information includes a processing time, a switching time, pressure (exhaust gas), high-frequency power, a voltage, various gas flow rate, a gas flow rate, a chamber inner temperature (for example, an upper electrode temperature, a chamber side wall temperature, a preset temperature for the wafer) , and so on. The recipe may be stored in a hard disk or a semiconductor memory. Further, the recipe may be stored in a recording medium readable by a portable computer such as a ROM, a DVD, or the like.

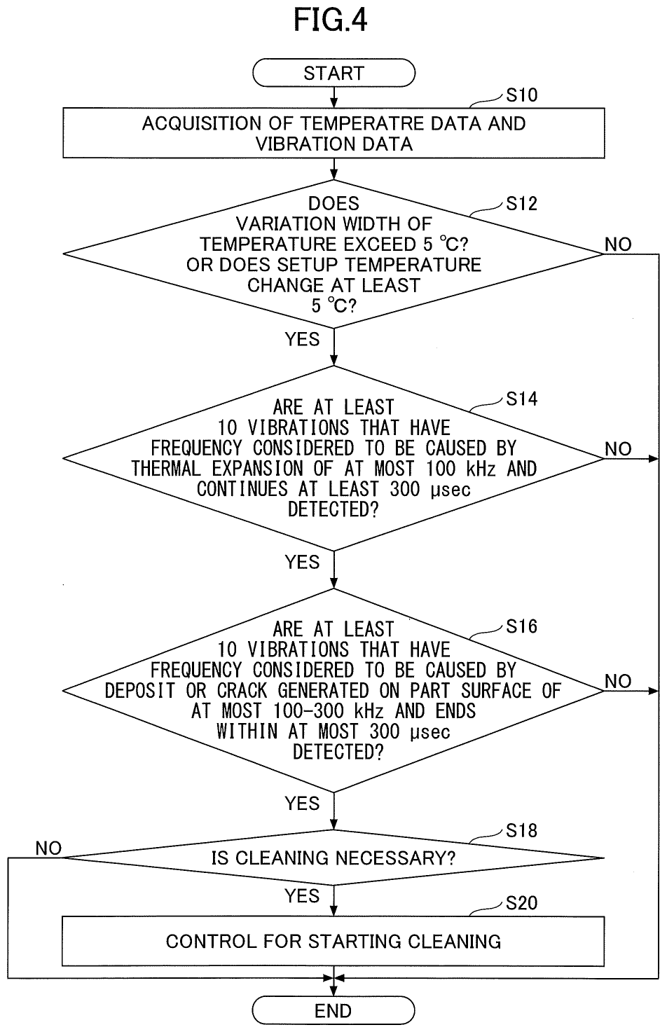

The CPU 103 controls an overall plasma processing apparatus 1 based on the basic program stored in the ROM 104. The CPU 103 controls a predetermined process such as an etching process for the wafer W in conformity with a procedure of the recipe stored in the RAM 105. The CPU 103 executes a cleaning process for the processing container 2 at a timing properly determined based on a maintenance control process (see FIG. 4) of the embodiment. In the wet cleaning, an upper part lid of the ceiling portion of the processing container 2 is opened, and a reaction product of an organic substance attached to the inner wall of the processing container 2 and the component part of the plasma processing apparatus 1. Cleaning conducted in this embodiment is not limited to wet cleaning but dry cleaning. Dry cleaning may be wafer-less dry-cleaning or dry-cleaning using wafer.

The display 106 displays an alert if the result of the maintenance requires so or other information to an operator. The speaker performs an audio output of an alert if the result of the maintenance requires so or reports the other information to the operator by sound.

### Hardware Structure of the Control Device

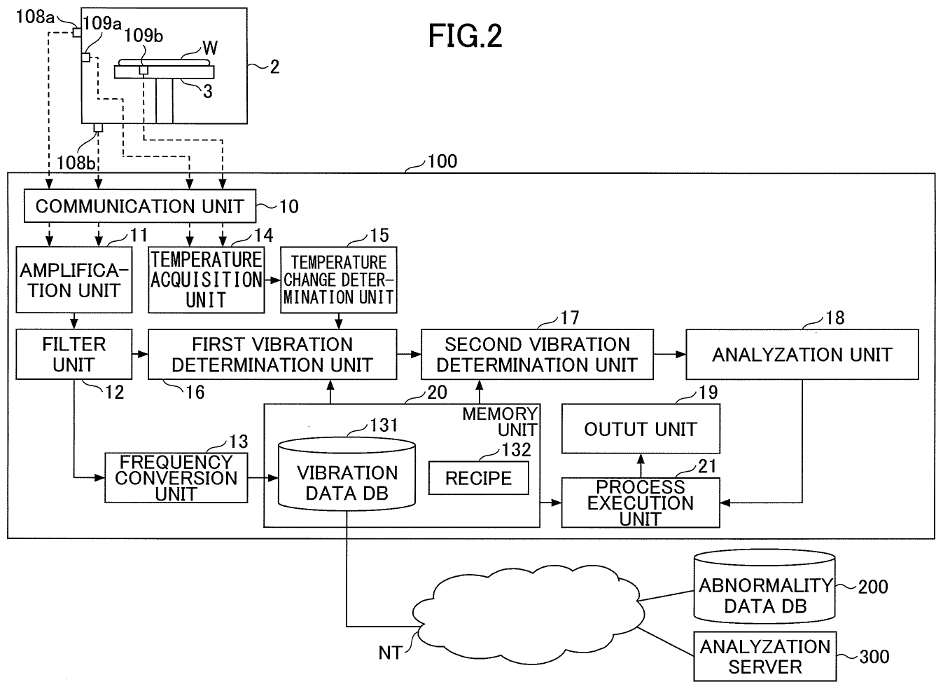

Referring to FIG. 2, described is an example of a functional structure of the control device 100. The control device 100 includes a communication unit 10, an amplification unit 11, a filter unit 12, a frequency conversion unit 13, a temperature acquisition unit 14, a temperature change determination unit 15, a first vibration determination unit 16, a second vibration determination unit 17, an analyzation unit 18, an output unit 19, a memory unit 20, a process execution unit 21.

The communication unit 10 receives a signal from the AE sensor 108 and the temperature sensor 109. The function of the communication unit 10 can be substantialized by, for example, a communication interface 110. The amplification unit 11 amplifies a vibration signal received through the communication unit 10. The function of the amplification unit 11 may be implemented by, for example, the amplifier 101. The filter unit 12 removes the error signal from the amplified vibration signal. The function of the filter unit 12 may be implemented by, for example, the filter 102.

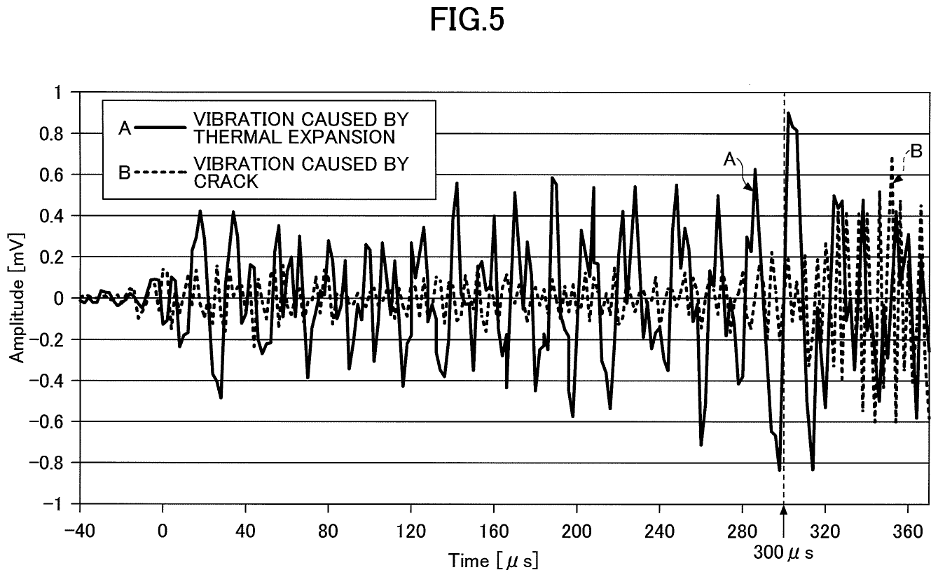

The frequency conversion unit 13 conducts frequency conversion for the vibration signal after filtering. With this, the vibration data in time series detected by using the AE sensor 108 is subjected to frequency conversion after amplifying and filtering and becomes data indicating a state of the vibration peak for each frequency. For example, FIG. 5 illustrates data in time series where the abscissa axis represents a time and the ordinate axis represents the intensity of vibration. The data illustrated in FIG. 5 are an example of the vibration data in time series detected by the AE sensor 108. Meanwhile, the vibration data after the frequency conversion become data indicating a vibration frequency property where the abscissa axis indicates the frequency and the ordinate axis indicates the intensity of vibration. The data subjected to the frequency conversion are stored in the vibration data DB 131 of the memory unit 20.

The temperature acquisition unit 14 acquires a temperature signal detected by the temperature sensor 109 through the communication unit 10. The temperature change determination unit 15 determines whether the temperatures of the wall of the processing container 2, the mounting stage, or the like changes by at least 5° C. based on the acquired temperature signal in time series. The temperature change determination unit 15 determines whether the preset temperature of the temperatures of the wall of the processing container 2, the mounting stage, or the like has been changed at least 5° C.

Within this embodiment, a timing of starting cleaning is controlled to prevent a particle from generating due to thermal expansion. Therefore, within this embodiment, it is determined whether the temperature of the wall of the processing container 2, the mounting stage, or the like increases at least 5° C. or the preset temperature of the wall of the processing container 2, the mounting stage, or the like is caused to be increased at least 5° C. With this, it is determined whether a situation in which the thermal expansion easily occurs in the component part of the processing container 2.

A conspicuous factor of generating a particle inside the processing container 2 is thermal expansion of a member caused by temperature increase. When the temperature increases inside the processing container 2, friction occurs between members due to a difference of the thermal expansion coefficient between the members if the temperature increases inside the processing container 2. Especially, if the temperature of the member increases at least 5° C., the friction generated between the members becomes large so as to easily peel a reaction product attached onto the surfaces of the members to be peel off. Therefore, the temperature increase of the member by at least 5° C. (or causing the preset temperature to increase at least 5° C.) interlocks with a timing of generating the particle.

A parameter giving a variation to the generation of the particle and a timing of generating the particle is considered to be, for example, the type of the member used for the plasma processing apparatus 1, the type of the plasma processing apparatus 1, and so on in addition to the temperature. However, in comparison with the temperature, the type of the member used for the plasma processing apparatus 1, the type of the plasma processing apparatus 1, and so on, has lower relevance. Therefore, within the embodiment, the condition for the determination is at a time when the temperature increases at least 5° C. or the preset temperature is caused to be increased at least 5° C. With this, when the temperature increases at least 5° C. or the preset temperature is caused to be increased at least 5° C., only the vibration data generated due to the thermal expansion can be made an analysis target. By this, an error detection can be reduced.

However, due to heat of plasma, a temperature change of about 10° C. may occur on the wall of the plasma processing apparatus 1. Therefore, in the first vibration determination unit 16 and the second vibration determination unit 17 described below, data other than the vibration data used for the analysis is subjected to screening from the vibration data provided with the first screening.

When the temperature of the wall or the mounting stage increases at least 5° C. or the preset temperature of the wall or the mounting stage is caused to be increased at least 5° C., the first vibration determination unit 16 performs following determination.

Within this embodiment, the temperature change determination unit 15 determines a change in the temperatures of the wall and the mounting stage of the processing container. However, regardless of this, the temperature change determination unit 15 may determine a temperature change of another component inside the processing container 2. Further, when the temperature of the wall changes at a predetermined rate or more based on a rate of changing the temperature in addition to the change in the temperature itself, the temperature change determination unit 15 may determine that a situation easily causing the thermal expansion to the component part of the processing container 2 occurs in a manner similar to a case where the temperature of the wall or the mounting stage increases at least 5° C. or the preset temperature of the wall or the mounting stage is caused to be increased at least 5° C.

In response to a timing when the temperature of the component changes at least 5° C. or the preset temperature of the component is caused to be changed at least 5° C., the first vibration determination unit 16 determines whether at least a predetermined number (10 vibrations in this embodiment) of “the first vibration” that has a frequency of at most 100 kHz, and has a vibration intensity of at least a predetermined intensity continued for at least 300 μs, is included in the vibration data detected by the AE sensor 108.

In a case where at least ten vibrations are determined to be included, the second vibration determination unit 17 determines whether the vibration data detected by the AE sensor 108 includes at least a predetermined number (ten in this embodiment) of “second vibration” that mainly has a frequency in a range of 100 kHz to 300 kHz, and has a vibration intensity of at least a predetermined intensity ending within at most 300 μs . However, the upper limit of the second vibration frequency may be 300 kHz or 500 kHz. Further, the AE sensor 108 may be selected as a sensor sensitive to a target frequency band.

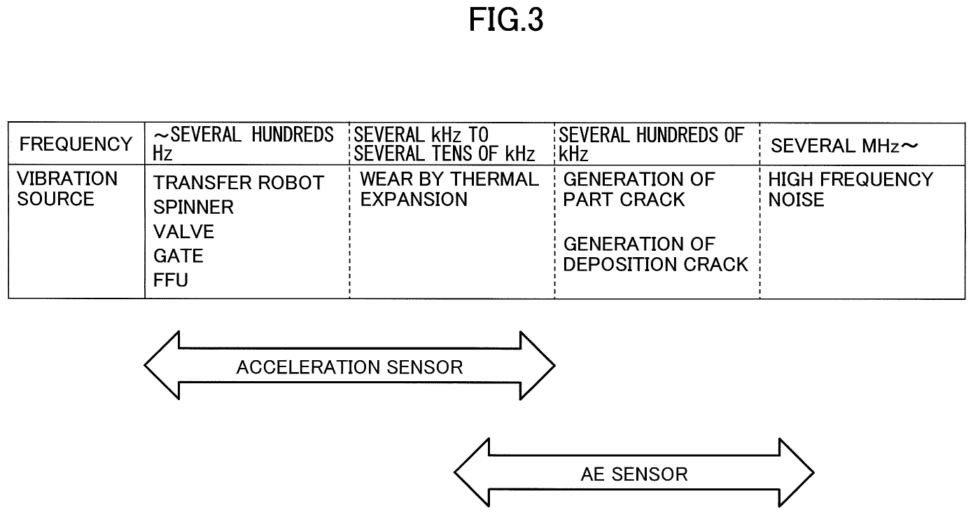

FIG. 3 illustrates the frequency band of the vibration detected by the AE sensor and the acceleration sensor and an example of the vibration source. The AE sensor can detect vibration in a frequency band higher than the frequency band detectable by the acceleration sensor. It is difficult for the acceleration sensor to detect the vibration of several hundreds of kHz. Therefore, it is preferable for this embodiment to use the AE sensor which can detect vibration of the several hundreds of kHz in comparison with the acceleration sensor.

Specifically, the AE sensor can detect the vibration in the frequency band of several tens of kHz to several hundreds of kHz. From among the vibration detected by the AF sensor, the vibration of several tens of kHz or the vibration at most 100 kHz is the vibration caused by friction due to thermal expansion. On the contrary thereto, the vibration of several hundreds of kHz, for example, the vibration data between 100 kHz and 300 kHz is vibration caused by generation of a parts crack or a crack of extraneous matter. The parts crack is generation of a crack mainly in a component itself provided inside the processing container 2. In the extraneous matter crack, the component itself provided inside the processing container 2 does not have a crack but the reaction product deposited on the surface of the component has a crack.

Therefore, by determining whether there is at least the predetermined number (10 vibrations in this embodiment) of “the first vibration” caused by the thermal expansion in the vibration data at the time when there is a temperature increase of the temperature of the mounting stage of at least 5° C., it is possible to determine whether friction is generated by the thermal expansion inside the processing container 2. By determining whether at least 10 vibration data caused by the friction due to thermal expansion are included in the vibration data, an erroneous determination can be reduced.

However, the number of the detected vibration data needs not to be at least 10 and may be another predetermined number. The data indicating the first vibration is specified from the test conducted by the inventor such that its frequency is at most 100 kHz, and the first vibration has a vibration intensity of at least a predetermined intensity continued for at least 300 μs.

In a case where the first vibration determination unit 16 determines that the vibration is generated due to the thermal expansion, the second vibration determination unit 17 determines whether at least 10 data indicating second vibration caused by crack of parts or crack of attached extraneous matter are included in the vibration data. With this, it is possible to determine whether the friction is caused in the inside of the processing container 2 due to the thermal expansion.

By determining whether at least 10 vibration data caused by the crack of parts or the crack of the attached extraneous matter is included in the vibration data, an erroneous determination can be reduced. However, the number of the detected vibration data needs not to be at least 10 and may be another predetermined number. The data indicating the second vibration is specified from the test conducted by the inventor such that its frequency is a frequency mainly in a range of 100 kHz to 300 kHz and the second vibration has a vibration intensity of at least a predetermined intensity to be ended within at most 300 μs.

The analyzation unit 18 analyzes a state of the plasma processing apparatus 1 based on the vibration data in which the first and second vibrations are included in a case where the second vibration determination unit 17 determines that at least a predetermined number of second vibration is included.

The analyzation unit 18 calculates the frequency center of gravity of the vibration data including the first and second vibrations and may analyze the state of the plasma processing apparatus 1 based on the frequency center of gravity. The analyzation unit 18 may calculate an average of the intensities of the frequencies by weighting the intensities of the frequencies of the vibration data including the first vibration and the second vibration so that a heavy weight is applied to the frequency having a high intensity and a light weight is applied to the frequency having a low intensity. This average of the intensities is the frequency center of gravity. The analyzation unit 18 may extract a signal continuous time of the vibration data having at least a predetermined intensity from among the vibration data including the first vibration and the second vibration. The analyzation unit 18 may extract a time of the vibration data having the maximum intensity from among the vibration data including the first vibration and the second vibration. The analyzation unit 18 may extract the vibration data having the maximum frequency from among the vibration data including the first vibration and the second vibration. The analyzation unit may use at least one of the extracted data along with the frequency center of gravity to analyze an inner state of the processing container 2.

The result obtained by the analyzation unit 18 is reported to the process execution unit 21. The process execution unit 21 controls a desired plasma process inside the processing container 2 in accordance with the recipe 132 stored in the memory unit 20. Further, the process execution unit 21 controls cleaning which is executed in the plasma processing apparatus 1 in response to the analyzation result obtained in the analyzation unit 18. The process execution unit 21 may control to conduct to conduct cleaning immediately or at a predetermined timing in response to the analyzation result obtained in the analyzation unit 18. The process execution unit 21 may output an alert for maintaining the plasma processing apparatus 1 in response to the analyzation result obtained in the analyzation unit 18. The output unit 19 outputs an alert for prompting maintenance in response to the control of the process execution unit 21.

The process execution unit 21 may store the vibration data including the first vibration and the second vibration as abnormity data in the memory unit 20. The process execution unit 21 may store only data of the first vibration and the second vibration in the memory unit 20. The process execution unit 21 may cause the vibration data including the first vibration and the second vibration to be stored in an external memory area through a network NT. The vibration data including the first vibration and the second vibration may be stored in a memory area on a server or a cloud, which are connected to the network NT (for example, an abnormity data DB 200 illustrated in FIG. 2). With this, the abnormity data indicated by the vibration data may be stored in a predetermined memory unit. Further, by causing only the abnormity data from among the vibration data detected by the AE sensor 108 to be stored in a memory area in a server or a cloud, which are connected to the network NT, the load of the network NT can be reduced.

The analyzation server 300 may analyze the presence of the abnormity in the plasma processing apparatus 1, a rational factor of the vibration, and a timing of cleaning the accumulated plasma processing apparatus 1. Not only the abnormity data extracted from the vibration data caused along with the temperature increase as described in this embodiment but also the abnormity data extracted from the vibration data caused along with the pressure change or other abnormity data may be stored. The timing for cleaning the plasma processing apparatus, the presence of the abnormity, and the rational factor of the abnormity may be analyzed using the accumulated abnormity data of multiple types. The data obtained as the result of the analysis may be used in designing the plasma processing apparatus 1.

### Gas and Reaction Product

In a case where an etching process is performed in thus structured plasma processing apparatus 1, an example of etching gas supplied is a fluorine-containing gas. Specifically, an example of the etching gas is fluorocarbon-based gas (CF₄, CHF₃, CH₂F₂, C₅F₈, etc.) halogen-based gas (Cl₂, F₂, Br₂, etc.) and halogenated hydrogen gas (HF, HCl, HBr, etc.).

An example of a reaction product attached to the inner wall of the processing container 2 is based on fluorocarbon polymer, halide, metal halide (AlF₃), and metal oxide (Al₂O₃, CuO, CuO₂, TiO₂).

In a case where a film deposition process using CVD is performed in the plasma processing apparatus 1, an example of film deposition gas is tungsten fluoride gas (WF₆, etc.), titanium chloride gas (TiCl₄, etc.), and chlorine fluoride gas (ClF₃, etc.).

An example of a reaction product attached to the inner wall of the processing container 2 is based on metal (W, Ti, Cu, etc.), metal oxide (WO₃, TiO₂, CuO, CuO₂, etc.), metal halide.

In a case where a film deposition process is performed by PVD in the plasma processing apparatus 1, a target to be used is metal (W, Ti, Cu, etc.), and metal oxide (WO₃, TiO₂, CuO, CuO₂, etc.).

An example of a reaction product attached to the inner wall of the processing container 2 is based on metal (W, Ti, Cu, etc.), and metal oxide (WO₃, TiO₂, CuO, CuO₂, etc.).

### Vibration Sensor

Within the embodiment, the AE sensor 108 is employed as the vibration sensor, and the acceleration sensor is not employed. As illustrated in FIG. 3, the reason why is a shift between frequency bands of the vibration detected by the AE sensor and the acceleration sensor. Said differently, the acceleration sensor does not detect the vibration of the frequency of at least 100 kHz. On the contrary thereto, the AE sensor detects the vibration of the frequency of at least 100 kHz.

As illustrated in FIG. 3, the vibration caused by the friction between members due to the thermal expansion generated as a result of a temperature change is included in the vibration of the frequency band of several kHz to several tens of kHz, which can be detected by using the AE sensor. Further, the vibration generated when the crack is generated in the part or when the crack is generated in the attached extraneous matter (the reaction product) is included in the vibration in the vibration of the frequency band of 100 kHz or more to 300 kHz or less, which can be detected by using the AE sensor. The “vibration caused by the friction between the members due to the thermal expansion” and “the vibration at a time when the crack is generated in the part or when the crack is generated in the attached extraneous matter” can be detected by using the AE sensor. Additionally, in a case where the AE sensor 108 is used, it is possible to distinguish from the vibration caused by other vibration source unnecessary for the maintenance control method of this maintenance control method. Meanwhile, the “vibration caused by the friction between the members due to the thermal expansion” and “the vibration at a time when the crack is generated in the part or when the crack is generated in the attached extraneous matter” are not be detected by using the acceleration sensor. Therefore, the AE sensor 108 is used to detect the vibration. However, the acceleration sensor may be used in addition to the AE sensor 108.

The AE sensor 108 is a piezoelectric element or an optical fiber. The piezoelectric element can detect the vibration with a high sensitivity. On the other hand, the optical fiber can be used in the explosion-proof environment because electricity is not used unlike the piezoelectric element. Further, measurement at many points is possible by wiring cables of the optical fiber.

In a case where the piezoelectric element is protected by heat insulating material, the temperature enabling the piezoelectric element to be used is about 80° C. or less. Meanwhile, the optical fiber has an advantage that a usable temperature range wider than that of the piezoelectric element, can be used under a high temperature environment of about 100° C. (more than 1000° C. in a specified feature) and can be used as a temperature sensor.

### Maintenance Control Process

Next, referring to a flowchart illustrated in FIG. 4, a maintenance control process is described. After this process is started, the temperature acquisition unit 14 acquires temperature data from a temperature signal detected by a temperature sensor 109 (Step S10). The amplification unit 11 acquires the vibration data from the vibration signal detected by the AE sensor 108 (Step S10) and appropriately amplify the signal.

Next, the temperature change determination unit 15 determines, based on the acquired temperature data, whether the temperature of the sidewall or the temperature of the mounting stage of the processing container 2 changes by at least 5° C. or whether the temperature of the sidewall or the temperature of the mounting stage of the processing container 2 is caused to be changed at least 5° C. (Step S12).

In a case where the temperature change determination unit 15 determines that the temperature of the sidewall or the temperature of the mounting stage of the processing container 2 does not change by at least 5° C. or that the temperature of the sidewall or the temperature of the mounting stage of the processing container 2 is not caused to be changed at least 5° C., this process ends. Meanwhile, in a case where the temperature change determination unit 15 determines that the temperature of the sidewall or the temperature of the mounting stage of the processing container 2 changes by at least 5° C. or that the temperature of the sidewall or the temperature of the mounting stage of the processing container 2 is caused to be changed at least 5° C., a determination by a first vibration determination unit 16 is performed. Said differently, the first vibration determination unit 16 determines whether the vibration data detected by the AE sensor 108 includes at least ten first vibrations supposed to be caused by the thermal expansion, mainly having a frequency of at most 100 kHz, and having a vibration intensity of at least a predetermined intensity continued for at least 300 μs, in response to a timing when the temperature of the sidewall, the temperature of the mounting stage of the processing container, or the like changes by at least 5° C. or when the temperature of the sidewall, the temperature of the mounting stage of the processing container, or the like is caused to be changed at least 5° C. (Step S14).

FIG. 5 illustrates data of the vibration A caused by the thermal expansion and data of the vibration B caused by the crack. In the data of the vibration A caused by the thermal expansion, the vibration mainly continues at least 300 μs. In the data of the vibration B caused by the crack, the vibration mainly continues at most 300 μs.

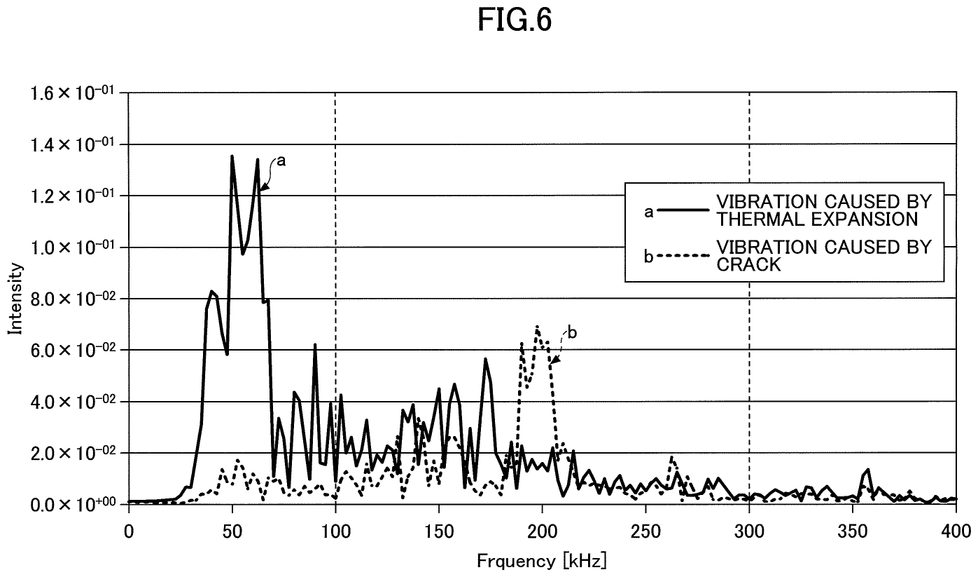

FIG. 6 illustrates data of vibration a caused by the thermal expansion and data of vibration b caused by the crack after conducting frequency conversion for the vibration data illustrated in FIG. 5. The data of the vibration a caused by the thermal expansion indicates that the frequency of the vibration a caused by the thermal expansion is mainly at most 100 kHz. Here, “mainly” in “the frequency of the vibration a caused by the thermal expansion is mainly at most 100 kHz” means that the peak frequency having the strongest signal strength comes at the position of at most 100 kHz from among the frequency components of the data of the vibration a caused by the thermal expansion. Therefore, “the frequency of the vibration a caused by the thermal expansion is mainly at most 100 kHz” means that the peak frequency of the vibration a caused by the thermal expansion is positioned at 100 kHz or lower and the frequency at skirt portions may position at 100 kHz or higher. The data of the vibration b caused by the crack indicates that the frequency of the vibration b caused by the crack is mainly in a range of 100 kHz to 300 kHz. Here, “mainly” in “the frequency of the vibration b caused by the crack is mainly in a range of 100 kHz to 300 kHz” means that the peak frequency having the strongest signal strength comes in a range of 100 kHz to 300 kHz from among the frequency components of the data of the vibration b caused by the crack. Therefore, “the frequency of the vibration b caused by the crack is mainly in a range of 100 kHz to 300 kHz” means that the peak frequency of the vibration b caused by the crack is positioned in the range of 100 kHz to 300 kHz and the frequency at skirt portions may position in a range other than the range of 100 kHz to 300 kHz.

Referring back to FIG. 4, in step S14, in a case where the first vibration determination unit 16 determines that the vibration data does not include at least ten first vibrations mainly having the frequency of at most 100 kHz and having the vibration intensity of at least a predetermined intensity continued for at least 300 μs, this process is ended. On the other hand, in a case where the first vibration determination unit 16 determines that the vibration data includes at least ten first vibrations mainly having the frequency of at most 100 kHz and having the vibration intensity of at least a predetermined intensity continued for at least 300 μs, the determination by the second vibration determination unit 17 is conducted.

Said differently, in the case where the first vibration determination unit 16 determines that the vibration data includes at least ten first vibrations, the second vibration determination unit 17 determines whether the vibration data detected by the AE sensor 108 includes at least ten second vibrations mainly having a frequency in the range of 100 kHz to 300 kHz and having a vibration intensity of at least a predetermined intensity ends within at most 300 μs (Step S16). The second vibration is vibration supposed to be caused by the crack generated on the attached extraneous matter or the surface of the part.

In a case where the second vibration determination unit 17 determines that the vibration data detected by the AE sensor 108 does not include at least ten second vibrations having the frequency in the range of 100 kHz to 300 kHz and having the vibration intensity of at least the predetermined intensity ends within at most 300 μs, this process ends.

Meanwhile, In a case where the second vibration determination unit 17 determines that the vibration data detected by the AE sensor 108 includes at least ten second vibrations having the frequency in the range of 100 kHz to 300 kHz and having the vibration intensity of at least the predetermined intensity ends within at most 300 μs, the analyzation unit 18 analyzes a state of the plasma processing apparatus based on the vibration data including the vibration and the second vibration and determines whether cleaning of this apparatus is necessary (Step S18). In a case where it is determined that the cleaning of this apparatus is necessary, the analyzation unit 18 controls to start the cleaning after a process being performed (Step S20) and this process is ended. On the other hand, in a case where it is determined that the cleaning of this apparatus is not necessary in step S18, this process is ended.

As described above, the maintenance control method of this embodiment, minute elastic vibration caused by peel-off of the reaction product attached to the processing container 2 by the AE sensor 108, elastic vibration of the component part forming the plasma processing apparatus 1, and friction vibration of the component part are detected. With this, a timing of maintenance of cleaning the inside of the plasma processing apparatus 1 can be predicted. Accordingly, a manufacturing plan can be accurately determined in advance.

Further, according to the maintenance control process of this embodiment, a cleaning cycle can be optimized any time in consideration of the inner state of the processing container 2. Therefore, it is possible to prevent particle from being generated earlier than a predetermined cycle, a defective product from being manufactured, and waste of earlier cleaning the plasma processing apparatus 1 which does not require the cleaning yet.

Specifically, the vibration data at a time corresponding to a temperature increase of 5° C. in a wall or a mounting stage or an increase of a setup temperature of the part by 5° C. are extracted from among the vibration data detected by the AE sensor 108. Therefore, only the vibration data caused by the thermal expansion can be a target of the analysis from among the detected vibration data.

Further, it is determined whether the vibration data extracted as the target of the analysis includes at least ten first vibration data having the frequency of at most 100 kHz and having the vibration intensity of at least the predetermined intensity continued for at least 300 μs. With this, it is possible to conduct screening of the vibration data caused by friction due to the thermal expansion and other data.

Further, it is determined whether the vibration data extracted as caused by the friction due to the thermal expansion from among the data of the target of the analysis include at least ten second vibration data having the frequency in the range of 100 kHz to 300 kHz and having the vibration intensity of at least a predetermined intensity ends within at most 300 μs. With this, it is possible to conduct screening of the vibration data caused by generation of the crack of the part or the crack in the attached extraneous matter.

The analyzation unit 18 can analyze the state of the film thickness of the reaction product or the state of the inside of the processing container 2 based on the extracted vibration data. As a result, an alert prompting to conduct the maintenance may be output or a timing of cleaning the inside of the processing container can be controlled by detecting the vibration caused when the crack is generated in the reaction product. With this, a timing of maintenance of cleaning the inside of the plasma processing apparatus 1 can be predicted while restricting the particle from being generated. As a result, improvement of product yield ratio, cost reduction of the gas due to the reduced number of times of cleaning, and improved throughput are obtainable. The order of processing step S14 and step S16 can be replaced, or the processes of step S14 and step S16 may be performed in parallel.

Although the maintenance control method of controlling the processing device and the control device are described in this embodiment, the maintenance control method of controlling the processing device and the control device of the present invention are not limited to the above embodiment and various modifications and alternations are possible within the scope of the present invention. The features described in the above multiple embodiments may be combined so as not to contradict one another.

For example, the control device 100 of the above embodiment may perform a maintenance control based on a vibration signal detected by one AE sensor or vibration signals detected by multiple AE sensors 108.

Further, the control device 100 can specify the position of the source of generating the vibration by installing multiple AE sensors 108 using the triangulation method. Furthermore, by adding a determination condition that the distance between the position of temperature change and the position of the vibration source is 10 cm or less, the accuracy of specifying the position of the generation source can be improved.

For example, the processing device of the present invention is applicable not only to a capacity-coupled type plasma (CCP: Capacitively Coupled Plasma) apparatus but also to another plasma processing apparatus. The other plasma processing apparatus may be an inductively-coupled type plasma (ICP: Inductively Coupled Plasma), a plasma processing apparatus using a radial line slot antenna, a helicon wave excitation type plasma (HWP: Helicon Wave Plasma) apparatus, an electron cyclotron resonance plasma (ECR: Electron Cyclotron Resonance Plasma) apparatus, or the like.

Furthermore, the processing device of the present invention is not limited to a plasma processing apparatus and may be an apparatus to whose wall the film or the attached extraneous matter attach. Although the specification has been described about the wafer as a substrate to be etched, the present invention is inclusively applicable to various substrates used for Liquid Crystal Display (LCD), Flat Panel Display (FPD) or the like, photo mask, a CD substrate, printed wiring board, or the like.

This international application is based on Japanese Priority Patent Application No. 2016-083960 filed on Apr. 19, 2016, the entire contents of which are hereby incorporated herein by reference.

### EXPLANATION OF REFERENCE SYMBOLS

1: plasma processing apparatus
2: processing container
3: lower electrode (mounting stage)
4: upper electrode
5: gas supply source
10: communication unit
11: amplification unit
12: filter unit
13: frequency conversion unit
14: temperature acquisition unit
15: temperature change determination unit
16: first vibration determination unit
17: second vibration determination unit
18: analyzation unit
19: output unit
20: memory unit
21: process execution unit
32: first high-frequency power source
34: second high-frequency power source
100: control device
101: amplifier
102: filter
103: CPU
104: ROM
105: RAM
106: display
107: speaker
108: AE sensor
109: temperature sensor
110: communication interface

1. A maintenance control method of controlling a processing device performed by a computer, the maintenance control method comprising:
determining whether a temperature of a component part of the processing device that processes a substrate changes at least 5° C. or a preset temperature is changed by at least 5° C.;
determining whether at least a predetermined number of a first vibration is included in vibration data detected by a vibration sensor provided in the processing device in response to a timing when the temperature of the component part of the processing device that processes the substrate is determined to change at least 5° C. or the preset temperature is determined to be changed by at least 5° C., the first vibration having a frequency of at most 100 kHz and having a vibration intensity of at least a predetermined intensity continued for at least 300 μs;
determining, in a case where the at least predetermined number of the first vibration is determined to be included in the vibration data, whether at least a predetermined number of a second vibration is included in the vibration data detected by the vibration sensor provided in the processing device, the second vibration having a frequency mainly in a range of 100 kHz to 300 kHz and having at least a predetermined vibration intensity to be ended within at most 300 μs; and
analyzing, in a case where the at least predetermined number of the second vibration is determined to be included in the vibration data, a state of the processing device based on the vibration data including the first vibration and the second vibration.

2. The maintenance control method according to claim 1,
wherein the maintenance is controlled in response to a result of the analyzing.

3. The maintenance control method according to claim 1,
wherein the processing device includes a plurality of vibration sensors,
wherein the maintenance control method further comprises:
determining whether at least a predetermined number of the first vibration is included in the vibration data detected by the plurality of vibration sensors; and
determining, in a case where at least the predetermined number of the first vibration is included in vibration data, whether at least a predetermined number of the second vibration is included in the vibration data.

4. The maintenance control method according to claim 1,
wherein the vibration sensor is a piezoelectric element or an optical fiber.

5. The maintenance control method according to claim 1,
wherein the vibration sensor is located at least any one position from among a position on an outer wall side of a processing container included in the processing device, a position on an inner wall side of the processing container, and a position inside a component part inside the processing container.

6. The maintenance control method according to claim 1,
wherein the maintenance is controlled in response to a result of the analyzing by controlling a timing of a start of cleaning the processing device or an output of an alarm prompting maintenance of the processing device.

7. The maintenance control method according to claim 5, the maintenance control method further comprising:
causing the vibration data including the first vibration and the second vibration to be stored in a memory unit or an external memory unit;
causing a factor of the vibration generated in the processing device to be analyzed by the processing device or an external device based on the vibration data stored in the memory unit or the external memory unit; and
using data obtained as a result of the analyzing in designing the processing device.

8. A control device of controlling a processing device comprising:
a temperature change determination unit configured to determine whether a temperature of a component part of the processing device that processes a substrate changes at least 5° C. or a preset temperature is changed by at least 5° C.;
a first vibration determination unit configured to determine whether at least a predetermined number of a first vibration is included in vibration data detected by a vibration sensor provided in the processing device in response to a timing when the temperature of the component part of the processing device that processes the substrate is determined to change at least 5° C. or the preset temperature is determined to be changed by at least 5° C., the first vibration having a frequency of at most 100 kHz and having at least a predetermined vibration intensity continued for at least 300 μs;
a second vibration determination unit configured to determine, in a case where the at least predetermined number of the first vibration is determined to be included in the vibration data, whether at least a predetermined number of a second vibration is included in the vibration data detected by the vibration sensor provided in the processing device, the second vibration having a frequency mainly in a range of 100 kHz to 300 kHz and having at least a predetermined vibration intensity to be ended within at most 300 μs; and
an analyzation unit configured to analyze, in a case where the at least predetermined number of the second vibration is determined to be included in the vibration data, a state of the processing device based on the vibration data including the first vibration and the second vibration.

9. The control device according to claim 8, the control device further comprising:
a process execution unit configured to control maintenance in response to a result of the analyzation.
